(19) United States
(12) Patent Application Publication
(10) Pub. No.: US 2025/0364296 A1
(43) Pub. Date: Nov. 27, 2025

(54) SEMICONDUCTOR WAFER, METHOD FOR PROCESSING SEMICONDUCTOR WAFER, AND PROCESSING APPARATUS

(71) Applicant: DISCO CORPORATION, Tokyo (JP)

(72) Inventor: Kazuma SEKIYA, Tokyo (JP)

(21) Appl. No.: 19/185,335

(22) Filed: Apr. 22, 2025

(30) Foreign Application Priority Data
May 21, 2024 (JP) 2024-082623

(51) Int. Cl. H01L 21/68; H01L 21/677

(52) U.S. Cl. CPC H01L 21/681; H01L 21/67769

(57) ABSTRACT

A semiconductor wafer has a first surface and a second surface which is a back surface opposite to the first surface. The semiconductor wafer has a circular shape having no cutout portion in a horizontal cross section.

### CROSS-REFERENCE TO RELATED APPLICATION(S)

The present application claims priority to and incorporates by reference the entire contents of Japanese Patent Application No. 2024-082623 filed in Japan on May 21, 2024.

### TECHNICAL FIELD

The present disclosure relates to a semiconductor wafer, a method for processing a semiconductor wafer, and a processing apparatus.

### BACKGROUND

In a wafer made of a semiconductor material, a cutout portion such as a notch or an orientation flat is formed on the outer periphery of the wafer as a mark indicating the crystal orientation of the wafer.

In a process of manufacturing a semiconductor device, a notch or an orientation flat is mainly used only for roughly aligning the orientation of the semiconductor wafer with respect to a pattern for patterning on a photosensitizer layer formed on the semiconductor wafer by an exposure apparatus.

Thus, a method for detecting a notch or the like has been conventionally used (see, for example, JP 2022-072520 A).

However, in a wafer having a notch or an orientation flat, the number of devices that can be formed on the surface is limited, and thus improvement has been desired.

### SUMMARY

A semiconductor wafer according to an aspect of the present disclosure is a semiconductor wafer having a first surface and a second surface which is a back surface opposite to the first surface. The semiconductor wafer has a circular shape having no cutout portion in a horizontal cross section.

A method for processing a semiconductor wafer according to another aspect of the present disclosure includes: preparing a semiconductor wafer having a circular shape with no cutout portion in a horizontal cross section; applying a photosensitizer to the semiconductor wafer to form a photosensitizer layer; exposing the photosensitizer layer to light via a mask or an optical modulator to transfer a pattern to the photosensitizer layer; and detecting a crystal orientation of the semiconductor wafer before the exposing. The exposing includes positioning the semiconductor wafer in a predetermined orientation with respect to the pattern based on the crystal orientation of the semiconductor wafer.

A processing apparatus according to still another aspect of the present disclosure includes: a cassette placement table on which a wafer cassette is placed; a holding unit that holds a semiconductor wafer; a crystal orientation detecting unit that detects a crystal orientation of the semiconductor wafer held by the holding unit; and a transport unit that transports the semiconductor wafer between the cassette placement table and the holding unit. The transport unit stores the semiconductor wafer into the wafer cassette such that the semiconductor wafer is in a predetermined orientation with respect to the wafer cassette based on the crystal orientation of the semiconductor wafer detected by the crystal orientation detecting unit.

### BRIEF DESCRIPTION OF THE DRAWINGS

FIG. 1 is a perspective view schematically illustrating a semiconductor wafer to be processed by a method for processing the semiconductor wafer according to a first embodiment;

FIG. 2 is a cross-sectional view taken along line II-II illustrated in FIG. 1;

FIG. 3 is a flowchart illustrating a procedure of the method for processing the semiconductor wafer according to the first embodiment;

FIG. 4 is a view schematically illustrating a photosensitizer layer forming step of the method for processing the semiconductor wafer illustrated in FIG. 3;

FIG. 5 is a perspective view schematically illustrating an example of a configuration of a processing apparatus that performs a crystal orientation detecting step and a wafer storing step of the method for processing the semiconductor wafer illustrated in FIG. 3;

FIG. 6 is a perspective view schematically illustrating the crystal orientation detecting step of the method for processing the semiconductor wafer illustrated in FIG. 3;

FIG. 7 is a side view schematically illustrating the crystal orientation detecting step of the method for processing the semiconductor wafer illustrated in FIG. 3;

FIG. 8 is a front view schematically illustrating a wafer cassette storing wafers in the wafer storing step of the method for processing the semiconductor wafer illustrated in FIG. 3;

FIG. 9 is a cross-sectional view taken along line IX-IX illustrated in FIG. 8;

FIG. 10 is a side view schematically illustrating a state in which the semiconductor wafer is placed on a stage in an exposing step of the method for processing the semiconductor wafer illustrated in FIG. 3;

FIG. 11 is a side view schematically illustrating a state in which a photosensitizer layer on the semiconductor wafer placed on the stage is exposed in the exposing step of the method for processing the semiconductor wafer illustrated in FIG. 3;

FIG. 12 is a side view schematically illustrating a state in which the photosensitizer layer on the semiconductor wafer placed on the stage is developed in the exposing step of the method for processing the semiconductor wafer illustrated in FIG. 3; and

FIG. 13 is a perspective view illustrating a modification of the semiconductor wafer illustrated in FIG. 1.

### DETAILED DESCRIPTION

An embodiment of the present disclosure will be described in detail with reference to the drawings. The present invention is not limited by the contents described in the following embodiments. In addition, components described below include those that can be easily assumed by those skilled in the art and those that are substantially the same. Furthermore, configurations described below can be appropriately combined. In addition, various omissions, substitutions, or changes in the configurations can be made without departing from the gist of the present invention.

### First Embodiment

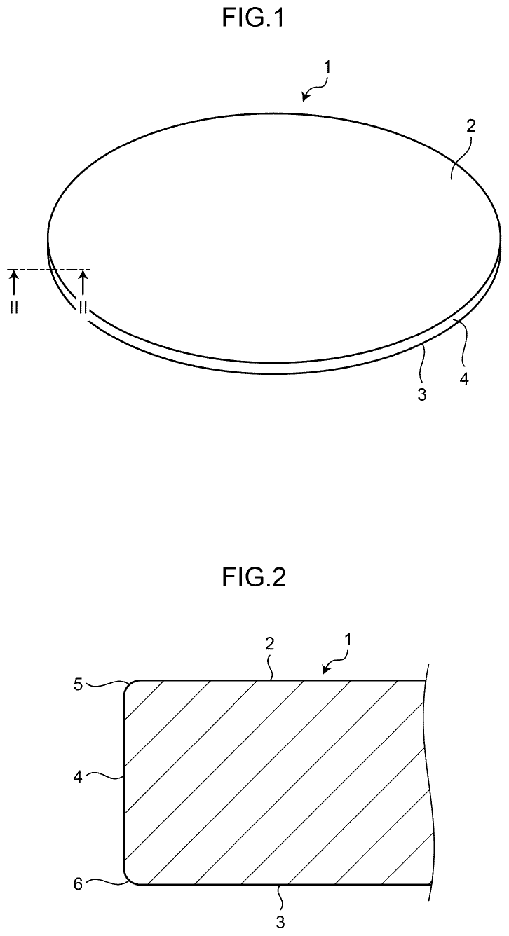

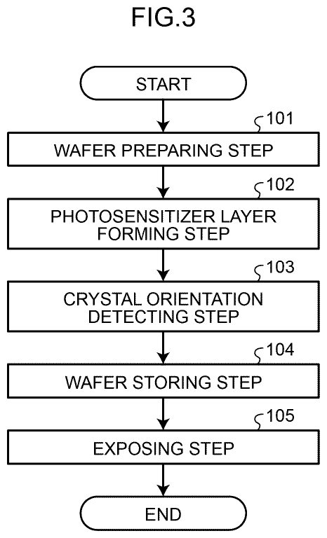

A method for processing a semiconductor wafer according to a first embodiment of the present invention will be described with reference to the drawings. FIG. 1 is a perspective view schematically illustrating the semiconductor wafer to be processed by the method for processing the semiconductor wafer according to the first embodiment. FIG. 2 is a cross-sectional view taken along line II-II illustrated in FIG. 1. FIG. 3 is a flowchart illustrating a procedure of the method for processing the semiconductor wafer according to the first embodiment.

### Semiconductor Wafer

The method for processing the semiconductor wafer according to the first embodiment is a method for processing the semiconductor wafer 1 illustrated in FIG. 1. The semiconductor wafer 1 to be processed by the method for processing the semiconductor wafer according to the first embodiment is made of silicon, and is formed in a disk shape as a whole as illustrated in FIG. 1 in the first embodiment. In the first embodiment, the semiconductor wafer 1 is made of single crystal silicon which is a semiconductor material. In the present invention, the semiconductor material constituting the semiconductor wafer 1 is not limited to silicon.

As illustrated in FIG. 1, the semiconductor wafer 1 has a circular first surface 2, a circular second surface 3 which is a back surface opposite to the first surface 2, and a side surface 4 extending from an outer edge of the first surface 2 to an outer edge of the second surface 3. The first surface 2 and the second surface 3 are formed flat, have the same diameter, and are disposed in parallel to each other.

In the first embodiment, as illustrated in FIG. 2, the side surface 4 of the semiconductor wafer 1 is formed in a straight line in a vertical cross section which is a cross section passing through the central axis of the semiconductor wafer 1, a first surface side surface chamfered portion 5 is formed at a corner between the first surface 2 and the side surface 4, and a second surface side surface chamfered portion 6 is formed at a corner between the second surface 3 and the side surface 4.

In the first embodiment, as illustrated in FIG. 2, the first surface side surface chamfered portion 5 is formed in an arc shape continuing from the first surface 2 to the side surface 4 in a vertical cross section of the semiconductor wafer 1, and the second surface side surface chamfered portion 6 is formed in an arc shape continuing from the second surface 3 to the side surface 4 in the vertical cross section of the semiconductor wafer 1. In the first embodiment, the chamfered portions 5 and 6 are formed by R-chamfering of R0.2 mm or less. In the present invention, the chamfered portions 5 and 6 may be formed into a so-called C surface having a tapered shape in which the diameter of the semiconductor wafer 1 decreases toward the first surface 2 or the second surface 3 in the above-described vertical cross section of the semiconductor wafer 1. In the first embodiment, the chamfered portions 5 and 6 may be formed by C-chamfering of C0.2 mm or less.

In the first embodiment, in the semiconductor wafer 1, a portion indicating a crystal orientation is not formed. That is, the semiconductor wafer 1 is formed in a disk shape having no cutout portion at the outer edge without forming a differently shaped portion (also referred to as a cutout portion) such as a notch or an orientation flat at the outer edge, and has a circular shape in a horizontal cross section parallel to the surfaces 2 and 3. In the first embodiment, the first surface 2 is a (100) plane of the semiconductor wafer 1.

### Method for Processing Semiconductor Wafer

As illustrated in FIG. 3, the method for processing the semiconductor wafer according to the first embodiment includes a wafer preparing step 101, a photosensitizer layer forming step 102, a crystal orientation detecting step 103, a wafer storing step 104, and an exposing step 105.

### Wafer Preparing Step

The wafer preparing step 101 is a step of preparing the semiconductor wafer 1 having the above-described configuration, that is, having the circular shape in the horizontal cross section parallel to the surfaces 2 and 3. In the first embodiment, the semiconductor wafer 1 described above is prepared by separating a portion from an ingot made of cylindrical single crystal silicon.

### Photosensitizer Layer Forming Step

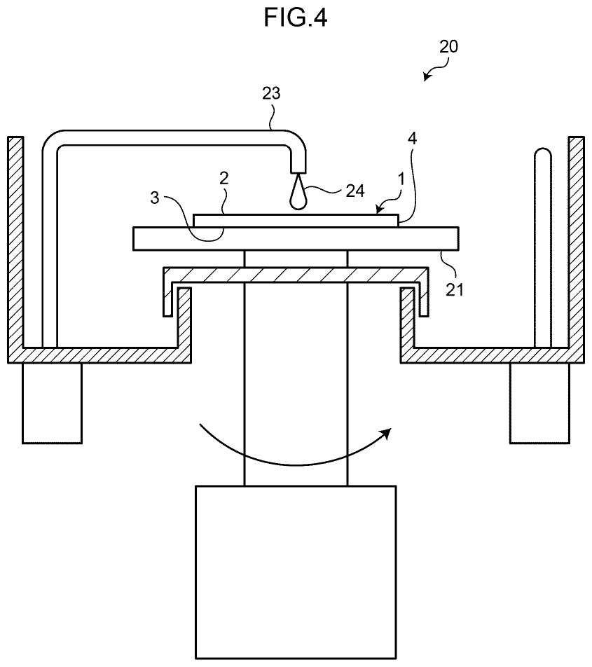

FIG. 4 is a view schematically illustrating the photosensitizer layer forming step of the method for processing the semiconductor wafer illustrated in FIG. 3. The photosensitizer layer forming step 102 is a step of applying a photosensitizer 24 to the semiconductor wafer 1 to form a photosensitizer layer (not illustrated).

In the first embodiment, in the photosensitizer layer forming step 102, a spin coater 20 illustrated in FIG. 4 holds the second surface 3 of the semiconductor wafer 1 on a holding surface of a spinner table 21 by suction. In the first embodiment, in the photosensitizer layer forming step 102, the spin coater 20 rotates the spinner table 21 about a central axis thereof, and drops the liquid photosensitizer 24 from a coating nozzle 23 to the center on the first surface 2 of the semiconductor wafer 1.

The dropped photosensitizer 24 flows from the central side toward the outer peripheral side on the first surface 2 of the semiconductor wafer 1 by centrifugal force generated by the rotation of the spinner table 21, and is applied to the entire first surface 2 of the semiconductor wafer 1 to form the photosensitizer layer. In the first embodiment, in the photosensitizer layer forming step 102, the spin coater 20 supplies the photosensitizer 24 for a predetermined time while rotating the spinner table 21 about the central axis to form the photosensitizer layer on the first surface 2 of the semiconductor wafer 1. In the present invention, the amount of the photosensitizer 24 dropped from the coating nozzle 23, the viscosity of the photosensitizer 24, and the rotation speed and rotation time of the spinner table 21 are set to values such that the photosensitizer 24 does not move onto the side surface 4 of the semiconductor wafer 1. In addition, it is desirable that the photosensitizer layer adhering to the side surface 4 of the semiconductor wafer 1 be removed from the side surface 4 of the semiconductor wafer 1.

### Processing Apparatus

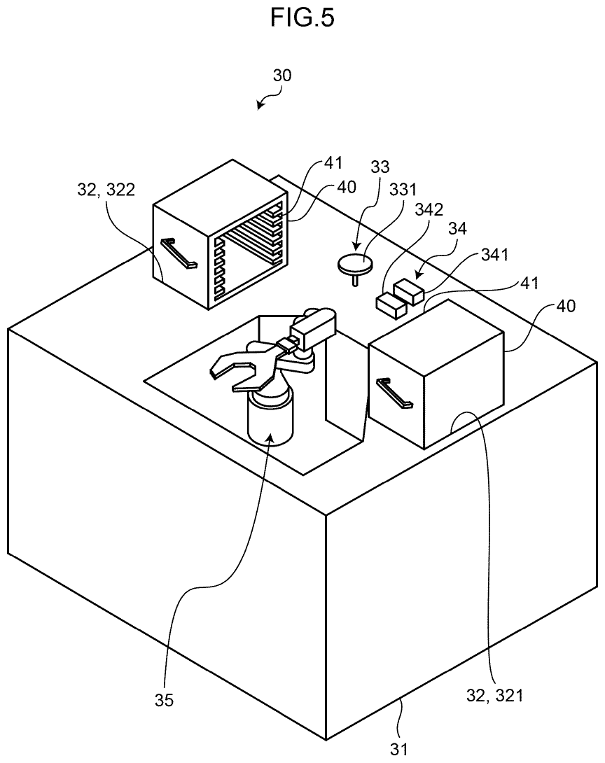

The crystal orientation detecting step 103 and the wafer storing step 104 are performed by a processing apparatus 30 illustrated in FIG. 5. Next, the processing apparatus 30 will be described. FIG. 5 is a perspective view schematically illustrating an example of a configuration of the processing apparatus that performs the crystal orientation detecting step and the wafer storing step of the method for processing the semiconductor wafer illustrated in FIG. 3.

The processing apparatus 30 detects the crystal orientation of the semiconductor wafer 1 as described in JP H11-014560 A. As illustrated in FIG. 5, the processing apparatus 30 includes an apparatus base 31, a pair of cassette placement tables 32 mounted on the apparatus base 31, a holding unit 33 mounted on the apparatus base 31, a crystal orientation detecting unit 34, a transport unit 35, and a control unit (not illustrated).

Wafer cassettes 40 are placed on the cassette placement tables 32, respectively. Each of the wafer cassettes 40 is a storage container that has a plurality of slots and stores a plurality of semiconductor wafers 1 at intervals in a vertical direction. The wafer cassettes 40 store a plurality of semiconductor wafers 1 before and after the crystal orientations are detected.

In the first embodiment, the cassette placement tables 32 support the wafer cassettes 40 to be movable up and down along the Z-axis direction. In the first embodiment, on the pair of cassette placement tables 32, the wafer cassettes 40 are placed such that openings 41 of the wafer cassettes 40 for taking in and out the semiconductor wafers 1 face each other. On the cassette placement table 32 (hereinafter, denoted by reference numeral 321) on the front side in FIG. 5 out of the pair of cassette placement tables 32, the wafer cassette 40 storing the semiconductor wafer 1 before the crystal orientation is detected is placed. The wafer cassette 40 storing the semiconductor wafer 1 of which the crystal orientation has been detected is placed on the cassette placement table 32 (hereinafter, denoted by reference numeral 322) on the back side in FIG. 4.

The holding unit 33 and the crystal orientation detecting unit 34 are provided between the pair of cassette placement tables 321 and 322 of the apparatus base 31. The holding unit 33 holds the semiconductor wafer 1 on an upper surface 331 formed flat along a horizontal direction. The holding unit 33 rotates about a central axis parallel to the vertical direction and is formed in a disk shape having a diameter smaller than that of the semiconductor wafer 1. The holding unit 33 holds the semiconductor wafer 1 on the upper surface 331 by suction.

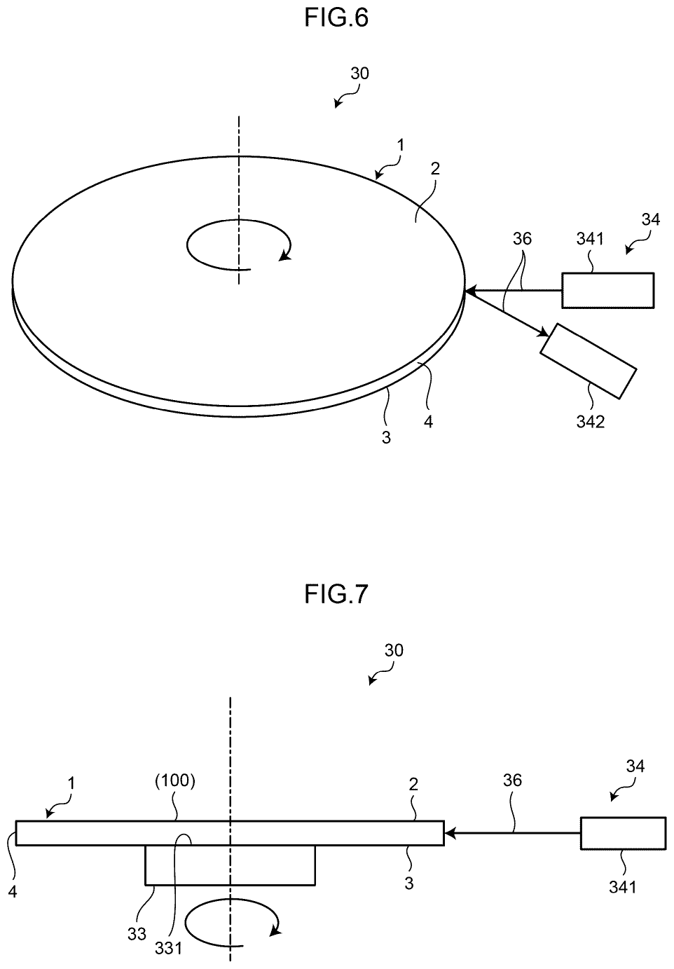

The crystal orientation detecting unit 34 detects the crystal orientation of the semiconductor wafer 1 held by the holding unit 33. The crystal orientation detecting unit 34 includes an X-ray irradiating unit 341 that causes an X-ray 36 (shown in FIG. 6) to be incident on the side surface 4 of the semiconductor wafer 1 held by the holding unit 33, and an X-ray receiving unit 342 that receives the reflected X-ray 36.

The transport unit 35 transports the semiconductor wafer 1 between the wafer cassettes 40 mounted on the cassette placement tables 321 and 322 and the holding unit 33. The transport unit 35 transports the semiconductor wafer 1 before the crystal orientation is detected from the wafer cassette 40 placed on the cassette placement table 321 to the holding unit 33, and transports the semiconductor wafer 1 of which the crystal orientation has been detected by the crystal orientation detecting unit 34 from the holding unit 33 to the wafer cassette 40 placed on the cassette placement table 322. In the first embodiment, the transport unit 35 is, for example, a robot pick including a U-shaped hand, and holds the semiconductor wafer 1 by suction with the U-shaped hand to transport the semiconductor wafer 1.

The control unit controls each component of the processing apparatus 30 to cause the processing apparatus 30 to perform an operation of detecting the crystal orientation for the semiconductor wafer 1. Note that the control unit is a computer including an arithmetic processing device having a microprocessor such as a central processing unit (CPU), a storage device having a memory such as a read only memory (ROM) or a random access memory (RAM), and an input/output interface device. The arithmetic processing device of the control unit performs arithmetic processing according to a computer program stored in the storage device, and outputs a control signal for controlling the processing apparatus 30 to each component of the processing apparatus 30 via the input/output interface device.

The control unit is connected to a display unit (not illustrated) including a liquid crystal display device or the like that displays a state of a processing operation, an image, and the like, and an input unit (not illustrated) used when an operator registers processing content information or the like. The input unit includes at least one of a touch panel provided on the display unit and an external input device such as a keyboard.

### Crystal Orientation Detecting Step

Next, the crystal orientation detecting step 103 will be described. FIG. 6 is a perspective view schematically illustrating the crystal orientation detecting step of the method for processing the semiconductor wafer illustrated in FIG. 3. FIG. 7 is a side view schematically illustrating the crystal orientation detecting step of the method for processing the semiconductor wafer illustrated in FIG. 3. The crystal orientation detecting step 103 is a step of detecting the crystal orientation of the semiconductor wafer 1 before the exposing step 105 is performed.

In the first embodiment, in the crystal orientation detecting step 103, the semiconductor wafer 1 is stored in the wafer cassette 40. At this time, the second surface 3 of the semiconductor wafer 1 is positioned downward, and the first surface 2 is exposed upward. In the first embodiment, in the crystal orientation detecting step 103, the semiconductor wafer 1 having the photosensitizer layer formed on the first surface 2 is stored in the wafer cassette 40.

In the first embodiment, in the crystal orientation detecting step 103, the wafer cassette 40 storing the semiconductor wafer 1 is placed on the cassette placement table 321, and the wafer cassette 40 not storing the semiconductor wafer 1 is placed on the cassette placement table 322. In the first embodiment, in the crystal orientation detecting step 103, a processing condition is registered in the control unit by the operator, and when the control unit receives an instruction to start a processing operation from the operator, the processing apparatus 30 starts the operation of detecting the crystal orientation. Note that the processing condition includes the crystal orientation of the semiconductor wafer 1 stored in the wafer cassette 40 placed on the cassette placement table 322.

In the first embodiment, in the crystal orientation detecting step 103, the processing apparatus 30 causes the control unit to cause the transport unit 35 to take out one semiconductor wafer 1 from the wafer cassette 40 placed on the cassette placement table 321 and place the semiconductor wafer 1 on the upper surface 331 of the holding unit 33.

In the first embodiment, in the crystal orientation detecting step 103, the processing apparatus 30 causes the control unit to hold the second surface 3 of the semiconductor wafer 1 on the upper surface 331 of the holding unit 33 by suction, causes the X-ray 36 to be incident on the side surface 4 of the semiconductor wafer 1 held by the holding unit 33 from the X-ray irradiating unit 341 while rotating the holding unit 33 about a central axis as illustrated in FIGS. 6 and 7, and causes the X-ray receiving unit 342 to receive the reflected X-ray 36. In the first embodiment, in the crystal orientation detecting step 103, the processing apparatus 30 causes the control unit to detect the crystal orientation of the semiconductor wafer 1 based on the intensity of the X-ray 36 received by the X-ray receiving unit 342.

In the present invention, the crystal orientation detecting step 103 may be performed before the photosensitizer layer forming step 102. In that case, it is desirable that the semiconductor wafer 1 be transported and processed in a constant operation until the semiconductor wafer 1 is carried out from the wafer cassette 40 in the photosensitizer layer forming step 102, the photosensitizer layer is formed, and the semiconductor wafer 1 is stored in the wafer cassette 40 again, and that the orientation of the semiconductor wafer 1 with respect to the wafer cassette 40 not be changed before and after the photosensitizer layer forming step 102.

### Wafer Storing Step

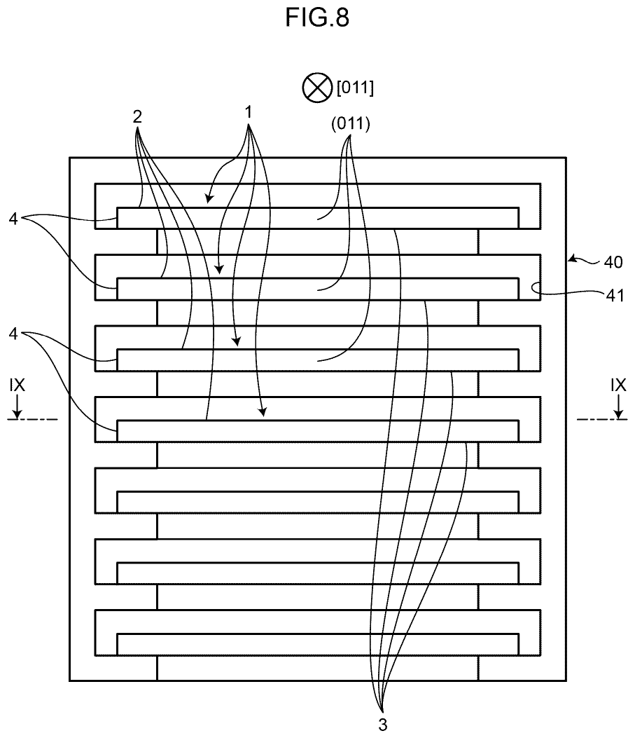

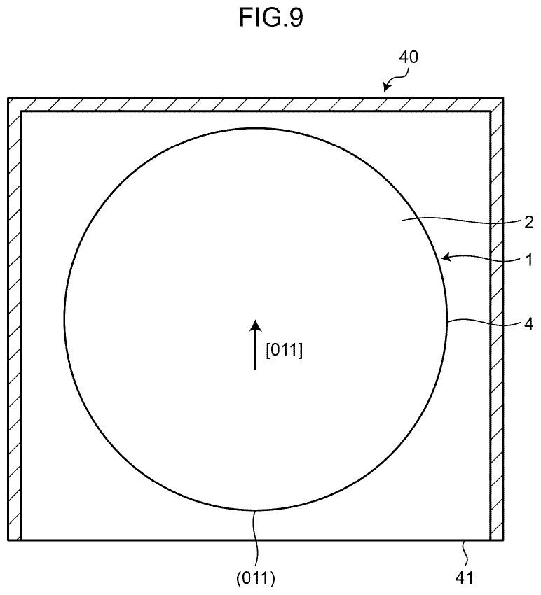

FIG. 8 is a front view schematically illustrating the wafer cassette storing wafers in the wafer storing step of the method for processing the semiconductor wafer illustrated in FIG. 3. FIG. 9 is a cross-sectional view taken along line IX-IX illustrated in FIG. 8. The wafer storing step 104 is a step of storing the semiconductor wafer 1 in the wafer cassette 40 such that the semiconductor wafer 1 is in a predetermined orientation with respect to the wafer cassette 40 based on the crystal orientation detected in the crystal orientation detecting step 103 after the crystal orientation detecting step 103 is performed and before the exposing step 105 is performed.

In the first embodiment, in the wafer storing step 104, the processing apparatus 30 stops the rotation of the holding unit 33 about the central axis and the holding of the semiconductor wafer 1 on the upper surface 331 by suction, and causes the transport unit 35 to transport the semiconductor wafer 1 from the upper surface 331 of the holding unit 33 into the wafer cassette 40 placed on the cassette placement table 322. At this time, in the first embodiment, in the wafer storing step 104, the processing apparatus 30 stores the semiconductor wafer 1 in the wafer cassette 40 by the transport unit 35 such that a (011) plane of the semiconductor wafer 1 is positioned at the center in the width direction of the semiconductor wafer 1 as viewed from the front of the opening 41 for taking in and out the semiconductor wafer 1 of the wafer cassette 40, for example, as illustrated in FIGS. 8 and 9.

Thus, in the wafer storing step 104, the semiconductor wafer 1 is stored in the wafer cassette 40 with the (011) plane positioned in a predetermined orientation with respect to the wafer cassette 40, so that the transport unit 35 stores the semiconductor wafer 1 into the wafer cassette 40 in such an orientation that the crystal orientation of the semiconductor wafer 1 is positioned in a predetermined orientation with respect to a pattern in the exposing step 105 based on the crystal orientation of the semiconductor wafer 1 detected by the crystal orientation detecting unit 34. In the present invention, the predetermined orientation in which the semiconductor wafer 1 after the detection of the crystal orientation is stored in the wafer cassette 40 is not limited to the orientation illustrated in FIGS. 8 and 9.

### Exposing Step

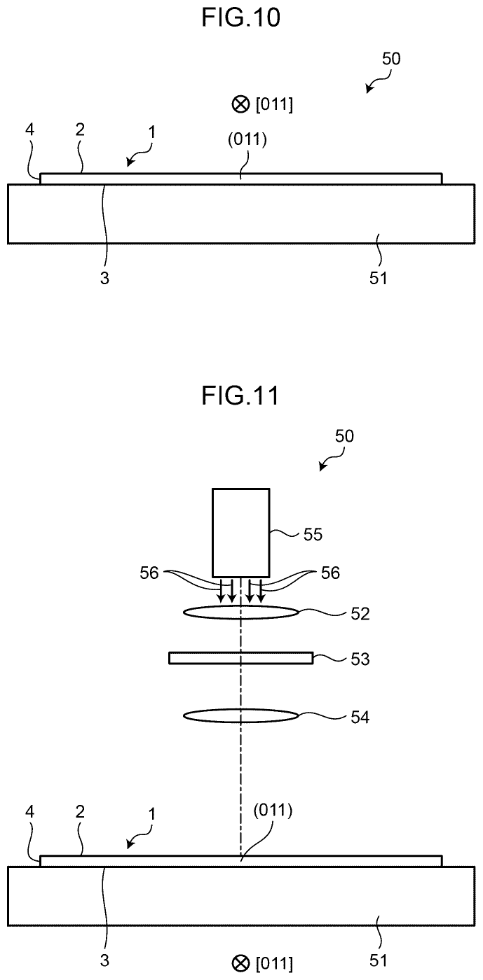

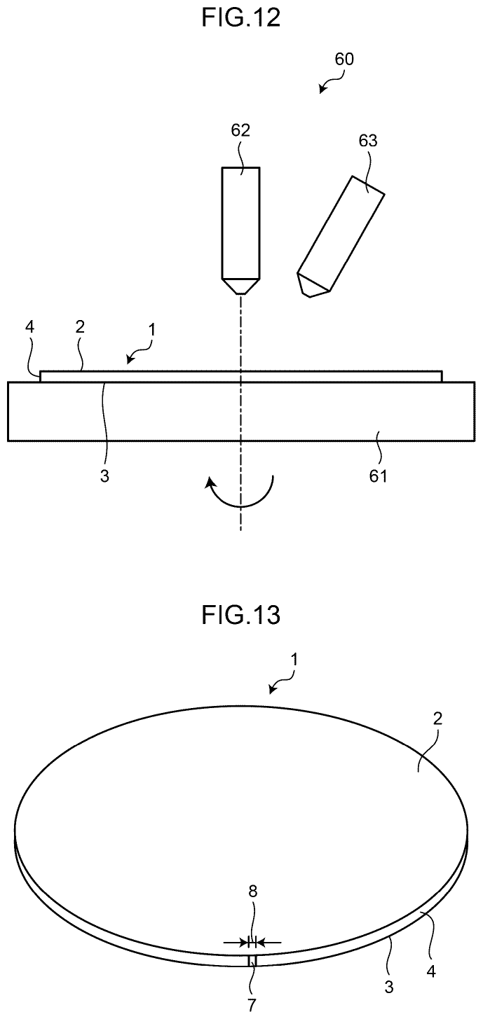

FIG. 10 is a side view schematically illustrating a state in which the semiconductor wafer is placed on a stage in the exposing step of the method for processing the semiconductor wafer illustrated in FIG. 3. FIG. 11 is a side view schematically illustrating a state in which the photosensitizer layer on the semiconductor wafer placed on the stage is exposed in the exposing step of the method for processing the semiconductor wafer illustrated in FIG. 3. FIG. 12 is a side view schematically illustrating a state in which the photosensitizer layer on the semiconductor wafer placed on the stage is developed in the exposing step of the method for processing the semiconductor wafer illustrated in FIG. 3.

The exposing step 105 is a step of irradiating the photosensitizer layer with light 56 (i.e., a step of exposing the photosensitizer layer to light 56) via a mask 53 or an optical modulator to transfer a pattern of a device to be formed on the first surface 2 to the photosensitizer layer. In the first embodiment, in the exposing step 105, in an exposure apparatus 50, the wafer cassette 40 in which the semiconductor wafer 1 has been stored in a predetermined crystal orientation in the wafer storing step 104 is placed on the cassette placement table (not illustrated).

In the first embodiment, in the exposing step 105, as illustrated in FIG. 10, the exposure apparatus 50 places the semiconductor wafer 1 on a stage 51 in a state where the semiconductor wafer 1 is positioned relative to the pattern in a predetermined manner based on the crystal orientation of the semiconductor wafer 1 stored in the wafer cassette 40. Specifically, in the first embodiment, in the exposing step 105, the transport unit transports the semiconductor wafer 1 from the wafer cassette 40 placed on the cassette placement table (not illustrated) in a constant operation, and places the semiconductor wafer 1 on the stage 51 in the exposure apparatus 50.

As such, in the exposing step 105, since the semiconductor wafer 1 is stored in the wafer cassette 40 in the predetermined orientation, the pattern of the mask 53 and the semiconductor wafer 1 are in a condition in which they are roughly aligned in position when the semiconductor wafer 1 is transported onto the stage 51. In the first embodiment, as illustrated in FIG. 10, the exposure apparatus 50 places the semiconductor wafer 1 on the stage 51 such that the (011) plane of the semiconductor wafer 1 is positioned at the center in the width direction of the semiconductor wafer 1 as viewed from the front of the stage 51.

In the first embodiment, in the exposing step 105, as illustrated in FIG. 11, the exposure apparatus 50 irradiates the photosensitizer layer on the semiconductor wafer 1 placed on the stage 51 with light 56 from a light source 55 through a condenser lens unit 52, the mask 53 according to the pattern, and a projection lens unit 54, and transfers the pattern to the photosensitizer layer. In the first embodiment, so-called maskless exposure in which light 56 is emitted via the optical modulator may be performed without using the mask 53. Thus, in the exposing step 105, the semiconductor wafer 1 is transported from the wafer cassette 40 to the stage 51, and the semiconductor wafer 1 supported by the stage 51 is irradiated with light 56.

In the first embodiment, in the exposing step 105, as illustrated in FIG. 12, the second surface 3 of the semiconductor wafer 1 exposed is placed on a table 61 in a developing apparatus 60, and the developing apparatus 60 uniformly applies a developer from a developer supply nozzle 62 onto the photosensitizer layer, and supplies a rinse solution from a rinse solution supply nozzle 63 to form a pattern on the first surface 2 of the semiconductor wafer 1. In the exposing step 105, in a case where the photosensitizer 24 is a positive resist, a pattern is formed on a portion not irradiated with light, and in a case where the photosensitizer 24 is a negative resist, a pattern is formed on a portion irradiated with light.

Thereafter, in the semiconductor wafer 1, etching, removal of the photosensitizer layer, formation of an insulating film, formation of an electrode layer, planarization, and the like are repeated to form a device on the first surface 2. Note that the device is, for example, an integrated circuit such as an integrated circuit (IC) or a large scale integration (LSI), an image sensor such as a charge coupled device (CCD) or a complementary metal oxide semiconductor (CMOS), or a memory (semiconductor storage device).

Since the semiconductor wafer 1 according to the first embodiment described above is formed in a disk shape having no cutout portion in the outer edge, there is an effect that a larger number of devices can be formed.

The semiconductor wafer 1 according to the first embodiment has an effect that a larger number of devices can be formed since the side surface 4 is formed in a straight line in a vertical cross section.

In the method for processing a semiconductor wafer according to the first embodiment, the semiconductor wafer 1 is positioned in the predetermined orientation with respect to the pattern of the mask 53 in the exposing step 105 based on the crystal orientation detected in the crystal orientation detecting step 103. Thus, in the method for processing a semiconductor wafer, a pattern can be transferred on the photosensitizer layer in a predetermined orientation even though the semiconductor wafer 1 does not have a cutout portion indicating the crystal orientation.

In the present invention, as illustrated in FIG. 13, in the semiconductor wafer 1, a linear mirror surface 7 may be formed on the side surface 4 indicating the crystal orientation. Note that FIG. 13 is a perspective view illustrating a modification of the semiconductor wafer illustrated in FIG. 1, and the same units as those in the first embodiment are denoted by the same reference numerals, and description thereof is omitted.

In the example illustrated in FIG. 13, the linear mirror surface 7 extends along the thickness direction of the semiconductor wafer 1 and is formed on the side surface 4 over the entire length in the thickness direction, but in the present invention, the linear mirror surface 7 may be formed on at least a portion of the semiconductor wafer 1 in the thickness direction. In the example illustrated in FIG. 13, the linear mirror surface 7 is formed along the (011) plane to be orthogonal to the crystal orientation [011] of the semiconductor wafer 1. The linear mirror surface 7 is formed as a mirror surface, and has the highest light reflectance in the side surface 4.

In the example illustrated in FIG. 13, the width 8 (chord length with respect to the circle of the outer peripheral edge of the semiconductor wafer 1) of the linear mirror surface 7 is 0.05 mm or more and 5 mm or less. The reason for setting the width 8 of the linear mirror surface 7 to be 0.05 mm or more and 5 mm or less is that, when the width 8 is less than 0.05 mm, the linear mirror surface 7 cannot be detected even when light is emitted and reflected light is received, and when the width 8 exceeds 5 mm, a variation in the timing of receiving the reflected light is large and a variation occurs in the orientation of the semiconductor wafer 1 stored in the wafer cassette 40, which is undesirable.

In the example illustrated in FIG. 13, the width 8 of the linear mirror surface 7 is 1 mm. In a case where the linear mirror surface 7 is formed as illustrated in FIG. 13, the crystal orientation of the semiconductor wafer 1 may be detected by irradiating the side surface 4 with light and detecting the linear mirror surface 7 based on the amount of light reflected from the side surface 4 in the crystal orientation detecting step 103.

According to the present disclosure, a larger number of devices can be formed.

Note that the present invention is not limited to the above embodiments. That is, various modifications can be made without departing from the gist of the present invention.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor wafer having a first surface and a second surface which is a back surface opposite to the first surface, wherein
the semiconductor wafer has a circular shape having no cutout portion in a horizontal cross section.

2. The semiconductor wafer according to claim 1, wherein
the semiconductor wafer has a side surface extending from the first surface to the second surface,
the side surface is formed in a straight line in a vertical cross section of the semiconductor wafer,
a first surface side chamfered portion is formed at a corner between the first surface and the side surface, and
a second surface side chamfered portion is formed at a corner between the second surface and the side surface.

3. A method for processing a semiconductor wafer, the method comprising:
preparing a semiconductor wafer having a circular shape with no cutout portion in a horizontal cross section;
applying a photosensitizer to the semiconductor wafer to form a photosensitizer layer;
exposing the photosensitizer layer to light via a mask or an optical modulator to transfer a pattern to the photosensitizer layer; and
detecting a crystal orientation of the semiconductor wafer before the exposing, wherein
the exposing includes positioning the semiconductor wafer in a predetermined orientation with respect to the pattern based on the crystal orientation of the semiconductor wafer.

4. The method for processing the semiconductor wafer according to claim 3, further comprising:
after the detecting and before the exposing, storing the semiconductor wafer in a wafer cassette such that the semiconductor wafer is in a predetermined orientation with respect to the wafer cassette in the detecting based on the crystal orientation detected, wherein
the exposing includes transporting the semiconductor wafer from the wafer cassette to a stage, and irradiating the semiconductor wafer supported by the stage with the light, and
the storing includes storing the semiconductor wafer in the wafer cassette in such an orientation that the semiconductor wafer is positioned in the predetermined orientation with respect to the pattern in the exposing.

5. A processing apparatus comprising:
a cassette placement table on which a wafer cassette is placed;
a holding unit that holds a semiconductor wafer;
a crystal orientation detecting unit that detects a crystal orientation of the semiconductor wafer held by the holding unit; and
a transport unit that transports the semiconductor wafer between the cassette placement table and the holding unit, wherein
the transport unit stores the semiconductor wafer into the wafer cassette such that the semiconductor wafer is in a predetermined orientation with respect to the wafer cassette based on the crystal orientation of the semiconductor wafer detected by the crystal orientation detecting unit.
